(19) United States
(12) Patent Application Publication
(10) Pub. No.: US 2025/0123330 A1
(43) Pub. Date: Apr. 17, 2025

(54) DESIGN FOR TEST SCANNING FOR LIGHT-EMITTING DIODE PACKAGES AND RELATED METHODS

(71) Applicant: CreeLED, Inc., Durham, NC (US)

(72) Inventor: Christopher P. Hussell, Raleigh, NC (US)

(21) Appl. No.: 18/488,186

(22) Filed: Oct. 17, 2023

(51) Int. Cl. G01R 31/3185; G01R 31/26; G09G 3/00

(52) U.S. Cl. CPC G01R 31/318572; G01R 31/2635; G01R 31/318555; G09G 3/006

(57) ABSTRACT

Light-emitting devices and, more particularly, design for test (DFT) scanning in light-emitting diode (LED) packages and related methods are disclosed. LED packages include one or more LED chips and an active electrical element capable of initiating DFT scanning. The active electrical element may be configured to receive scan initiation commands via a same data stream that includes other commands and data for controlling operation of the one or more LED chips. By using a same data stream, the active electrical element and LED package may be configured to implement DFT scanning without requiring separate ports for receiving DFT specific signals. The active electrical element may generate a test mode select (TMS) signal that is internal to the active electrical element upon receipt of a scan initiation command, and the TMS signal is used to trigger DFT scanning within the active electrical element.

### FIELD OF THE DISCLOSURE

The present disclosure relates to light-emitting devices and, more particularly, to design for test (DFT) scanning for light-emitting diode (LED) packages and related methods.

### BACKGROUND

Light-emitting diodes (LEDs) are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LEDs have been widely adopted in various illumination contexts, for backlighting of liquid crystal display (LCD) systems (e.g., as a substitute for cold cathode fluorescent lamps) and for direct-view LED displays. Applications utilizing LED arrays include vehicular headlamps, roadway illumination, light fixtures, and various indoor, outdoor, and specialty contexts. Desirable characteristics of LED devices include high luminous efficacy and long lifetime.

Large format multi-color direct-view LED displays (including full color LED video screens) typically include numerous individual LED panels, packages, and/or components providing image resolution determined by the distance between adjacent pixels. Direct-view LED displays typically include three-color displays with arrayed red, green, and blue (RGB) LEDs, and two-color displays with arrayed red and green (RG) LEDs. For many LED display systems, it is desirable to form LED color groups for each pixel such as primary colors red, green, and blue (RGB) that define vertices of a triangle (or polygon) on a chromaticity diagram. This polygon defines the so-called color gamut of the display device, the area of which describes all the possible colors that the display device is capable of producing. Driver printed circuit boards for controlling LED displays are typically densely populated with electrical devices including capacitors, field effect transistors (FETs), decoders, microcontrollers, and the like for driving the pixels of the display. As pixel pitches continue to decrease for higher resolution displays, the density of such electrical devices scales higher corresponding to the increased number of pixels for a given panel area. This tends to add higher complexity and costs to LED panels for display applications.

The art continues to seek improved LED array devices with small pixel pitches while overcoming limitations associated with conventional devices and production methods.

### SUMMARY

The present disclosure relates to light-emitting devices and, more particularly, to design for test (DFT) scanning in light-emitting diode (LED) packages and related methods. LED packages include one or more LED chips and an active electrical element capable of initiating DFT scanning. The active electrical element may be configured to receive scan initiation commands via a same data stream that includes other commands and data for controlling operation of the one or more LED chips. By using a same data stream, the active electrical element and LED package may be configured to implement DFT scanning without requiring separate ports for receiving DFT specific signals. The active electrical element may generate a test mode select (TMS) signal that is internal to the active electrical element upon receipt of a scan initiation command, and the TMS signal is used to trigger DFT scanning within the active electrical element.

In one aspect, an LED package comprises: at least one LED chip; an active electrical element electrically connected to the at least one LED chip, the active electrical element configured to implement design for test (DFT) scanning; and a data input port configured to receive commands and data for controlling operation of the at least one LED chip, the data input port configured to receive a scan initiation command to initiate DFT scanning within the active electrical element. In certain embodiments, the data input port is a first bidirectional communication port. In certain embodiments, the active electrical element is configured to detect an input signal at the first bidirectional communication port, assign the first bidirectional communication port as the data input port, and assign a second bidirectional communication port as a data output port. In certain embodiments: the at least one LED chip comprises three LED chips; and the active electrical element comprises no more than eight total ports that include the data input port, a data output port, a ground port, a supply voltage port, and no more than four ports coupled to the three LED chips. In certain embodiments, the active electrical element comprises no more than three ports coupled to the three LED chips. In certain embodiments, the active electrical element comprises a serial interface coupled to the data input port configured to receive the commands and data for controlling operation of the at least one LED chip and the scan initiation command. The LED package may further comprise scanner circuitry coupled to the serial interface, the scanner circuitry configured to pass the commands and data for controlling operation of the at least one LED chip and the scan initiation command to other circuitry of the active electrical element. In certain embodiments, the other circuitry forms scanned system circuitry of the active electrical element, and upon receipt of the scan initiation command, the scanned system circuitry generates a test mode select (TMS) signal that is sent to the scanner circuitry for initiating DFT scanning. In certain embodiments, the active electrical element comprises an application-specific integrated circuit (ASIC).

In another aspect, a method of testing for an LED device comprises: receiving commands and data at a data input port, the commands and data configured for controlling operation of at least one LED chip; receiving a scan initiation command for initiation of design for test (DFT) scanning at the data input port; and generating a test mode select (TMS) signal based on the scan initiation command. In certain embodiments, the data input port is a terminal of an active electrical element of the LED device. In certain embodiments, generating the TMS signal comprises receiving the scan initiation command at scanned system circuitry of the active electrical element. The method may further comprise sending the TMS signal to scanner circuitry of the active electrical element and implementing DFT scanning of the scanned system circuitry.

In another aspect, an active electrical element for controlling operation of at least LED comprises: a serial interface configured to receive commands and data for controlling operation of the at least one LED chip and a scan initiation command to initiate design for test (DFT) scanning; scanner circuitry coupled to the serial interface; and scanned system circuitry coupled to the scanner circuitry, the scanned system circuitry configured to generate a test mode select (TMS) signal based on the scan initiation command and send the TMS signal to the scanner circuitry for initiating DFT scanning. In certain embodiments, the scanner circuitry is configured to pass the commands and data for controlling operation of the at least one LED chip and the scan initiation command to the scanned system circuitry before the TMS signal is generated. The active electrical element may further comprise a data input port that is configured to receive both the scan initiation command and the commands and data for controlling operation of the at least one LED chip. In certain embodiments, the data input port is a first bidirectional communication port. In certain embodiments, the active electrical element is configured to detect an input signal at the first bidirectional communication port, assign the first bidirectional communication port as the data input port, and assign a second bidirectional communication port as a data output port. The active electrical element may further comprise a data output port, a ground port, a supply voltage port, and ports for coupling to one or more LED chips. In certain embodiments, the serial interface, the scanner circuitry, and the scanned system circuitry are part of an application-specific integrated circuit (ASIC).

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a block diagram illustrating a system level control scheme for a lighting device using cascade communication for serially connected light-emitting diode (LED) packages according to principles of the present disclosure.

FIG. 2 is a block diagram of an LED package from FIG. 1 capable of design for test (DFT) scanning according to principles of the present disclosure.

FIG. 3 is a top view of an active electrical element capable of DFT scanning according to principles of the present disclosure.

FIG. 4 is a schematic diagram illustrating a general process flow for a method of implementation of DFT scanning according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting devices and, more particularly, to design for test (DFT) scanning in light-emitting diode (LED) packages and related methods. LED packages include one or more LED chips and an active electrical element capable of initiating DFT scanning. The active electrical element may be configured to receive scan initiation commands via a same data stream that includes other commands and data for controlling operation of the one or more LED chips. By using a same data stream, the active electrical element and LED package may be configured to implement DFT scanning without requiring separate ports for receiving DFT specific signals. The active electrical element may generate a test mode select (TMS) signal that is internal to the active electrical element upon receipt of an scan initiation command, and the TMS signal is used to trigger DFT scanning within the active electrical element.

In cascade digital communication, multiple electronic devices are arranged as repeaters to successively receive serial communication for operation. In the context of fine-pitch video displays, multiple LED packages are serially arranged as LED pixels to receive cascade communication. Incoming signals to each LED pixel are produced by another element, such as a master controller or the previous LED pixel, and the bitstream of incoming signals is derived from clock domains of one or more preceding devices. Proper distribution of communication signals to thousands of LED pixels creates challenges. Small sizes are required for LED packages to form pixels of high-resolution video displays and these size constraints provide further challenges.

As used herein, the terms “data stream” and “communication channel” may at times be used interchangeably. However, a “data stream” generally refers to a non-physical representation of data over time that flows through a set of at least one communication channel as well as the internal wiring and storage registers within various elements such as controllers and active electrical elements. A data stream may also be referred to as digital communication between two elements, such as a controller element that transmits digital communication and a receiver element that receives the digital communication. A “communication channel” generally refers to a physical medium through which the data stream is conveyed. For example, a communication channel may comprise a wire with associated electrical elements, an optical fiber, or even air as in the case of radio, light, or sound waves. A given physical channel could also be divided up in time or frequencies to allow multiple “communication channels” within one medium at once such as changing to a different frequency band. In certain aspects, communication channels may embody serial digital communication channels. Certain aspects relate to a binary communication channel that is a single wire referenced to a common conductor such as ground, which commonly can only hold one value at a time which is high or low voltage (e.g., digital “0” or “1”) and is controlled by the output register of the preceding device. Two-wire differential signaling methods are also contemplated, but the preferred embodiment shown here refers to the single-wire approach primarily because of the added complexity of providing more traces with fine pitch displays.

In certain aspects, the present disclosure relates to light-emitting devices including LEDs, LED packages, and related LED displays and, more particularly, to active control of LEDs within LED displays. LED displays may include rows and columns of LEDs that form an array of LED pixels. A particular LED pixel may include a cluster of LED chips of the same color or multiple colors, with an exemplary LED pixel including a red LED chip, a green LED chip, and a blue LED chip. In certain embodiments, an LED package includes a plurality of LED chips that form at least one LED pixel, and a plurality of such LED packages may be arranged to form an array of LED pixels for an LED display. Each LED package may include its own active electrical element that is configured to receive a control signal and actively maintain an operating state, such as brightness or grey level or a color select signal for the LED chips of the LED device while other LED devices are being addressed. In certain embodiments, the active electrical element may include active circuitry that includes one or more of a driver device, a signal conditioning or transformation device, a memory device, a decoder device, an electrostatic discharge (ESD) protection device, a thermal management device, a detection device, a voltage and/or current sensing device, a command processing device, and other circuitry, among others. The active electrical element further includes circuitry to facilitate communication with multiple uncorrelated clock domains, including an original clock domain from a controller and a local clock domain derived within the active electrical element. In this regard, each LED pixel of an LED display may be configured for operation with active matrix addressing with mixed clock domain communication. The active electrical element may be configured to receive one or more of an analog control signal, an encoded analog control signal, a digital control signal, and an encoded digital control signal. In such arrangements, strings of LED packages, each with their own active electrical element, may be arranged for serial communication where each active electrical element receives data from a data stream and transmits data to the next active electrical element in the string of LED packages.

For active matrix addressing, each LED pixel is configured to actively maintain an operating state or otherwise control the driving state, such as brightness or grey level or color select, while other LED pixels are being addressed, thereby allowing each LED pixel to maintain or otherwise independently control their driving state and provide improved display and/or image recording with photographic equipment by reducing or eliminating effects caused by lower-frequency pulsing beating of the display light output with other non-synchronized equipment (e.g., lighting sources, other pulsed displays, or image capture equipment). Accordingly, each LED pixel may be configured to hold its respective operating state with a continuous drive signal, inclusive of pulse-width modulation (PWM), rather than by conventional methods using time division multiplexed signals scanning among groups of pixels that often result in the addition of low frequency components to the drive signals associated with passive matrix addressing. In this regard, each LED pixel may include an active electrical chip or an active electrical element that may include a memory device and the ability to alter a driving condition of the LED pixel based on a state stored in the memory of the active electrical element. In certain embodiments, the continuous drive signal is a constant analog drive current, and in other embodiments where the brightness level may be controlled by pulsed methods such as PWM, the continuous drive signal may refer to a PWM signal that is not interrupted by the time division multiplexed scanning of other LED pixels within the array or within a sub-array. In various embodiments, an active electrical element comprises an integrated circuit chip, an application-specific integrated circuit (ASIC), a microcontroller, or a field-programmable gate array (FPGA). In certain embodiments, active electrical elements may be configured to be programmable or reprogrammable after they are manufactured through various memory elements and logic that are incorporated within the active electrical elements.

As used herein, the terms “active electrical chip,” “active electrical element,” or “active electrical component” include any chip or component that is able to alter a driving condition of an LED based on memory or other information that may be stored within a chip or component. As used herein, the terms “active LED pixel” and “smart LED pixel” may be used interchangeably and may refer to a device that includes one or more LED devices or chips that form a pixel and an active electrical element or chip as described above. In certain embodiments, each LED pixel may comprise a single LED package that is configured as an active LED package that includes multiple LED chips and an active electrical element as described above. In this manner, the number of separate electrical devices needed for the LED display may be reduced, such as the separate electrical devices located on the backsides of LED panels of the LED display as previously described. Additionally, overall operating powers needed for operation of the LED panels may be reduced.

Performance of LED displays continues to advance. Previously, LED displays were more adept for static images such as LED signs rather than dynamic application such as video displays since many of the performance metrics expected for good video image display were lacking. Various performance metrics needed for consideration of LEDs for high-quality video display include resolution, contrast, viewing angle, dynamic range, brightness, frame rate, and color gamut, among others. Recent advancements in LED packages, improvements in LED driver quality, and cost reductions have greatly improved the resolution, among other requirements. As the resolution has increased, the packing density of LED packages, such as on printed circuit boards (PCBs), has also increased and become more complex. The driving of LEDs within LED packages to achieve high dynamic range simultaneously with high frame and refresh rates remains challenging. This is because current driving techniques require remote drivers placed on the opposing side of PCBs containing LED arrays. Packing density constraints dictate that the drivers need to be shared via time division multiplexing techniques, such as raster scan. As the preferred driving techniques for LEDs utilize PWM to set the brightness, ever-higher frequencies are required to achieve high dynamic range. Consequently, the dynamic range is limited by the highest frequency pulse that can be delivered in view of parasitic resistance, capacitance, and inductance. LED packages arranged as pixels for cascade serial communication afford the opportunity to provide drivers local to each LED package, thereby providing improved dynamic range by removing the need for shared drivers and greatly reducing the parasitic resistance, capacitance, and inductance.

DFT scanning is generally used for testing ASICs and other circuitry in very large-scale integration (VLSI) applications. DFT protocols are generally well known for testing such integrated circuits post-fabrication and Joint Test Action Group (JTAG) is a common interface to accomplish testing. Traditional JTAG and DFT scanning is usually implemented by design houses to operate as an overriding controller of an integrated circuit (IC) chip having the ability to stop normal operation, input-scan a test pattern into the internal registers while reading out their current state, allow one normal clock pulse to advance the system to its next state (commonly referred to as “capture”), and output-scan the contents of the registers while reading back in the next test pattern or the state for the device to resume normal operation. The use of JTAG to do this requires adherence to some JTAG specs which at least require a separate clock and data connection to the IC chip. In this regard, at least one extra input/output terminal or port is needed on the IC chip in order to select and implement testing. For example, a typical JTAG interface involves adding terminals to the IC chip that include a terminal for receiving a test mode select (TMS) signal. Additional terminals associated with a JTAG interface include test data in (TDI), test data out (TDO), test clock (TCK), and an optional test reset (TRST). While some of the JTAG terminals may have a dual purpose, being shared among the other terminals associated with other operational tasks of the ASIC, at least one unshared additional external terminal such as the TMS is generally required as a signal to the ASIC for which purpose the other terminals are to be used. This not only would occupy more real estate on the ASIC, but also would require bonding to an additional lead on the LED package if the features of DFT are to be realized in the packaged LED component and system as a whole.

In the context of LED packages for use as pixels in fine-pitch video displays, spacing between LED packages may be such that it prohibits additional connection ports or terminals. According to principles of the present disclosure, LED packages include active electrical elements capable of implementing DFT scanning within the LED package without requiring additional ports typically associated with DFT scanning and JTAG interfaces. For example, an LED package may include an active electrical element with an input port capable of receiving commands and data for controlling operation of one or more LED chips with the LED package. The same input port may also be capable of receiving an initiation command that initiates DFT scanning. In response to receiving the DFT scan initiation command, internal circuitry of the active electrical element may generate an internal TMS signal to scanning circuitry within the active electrical element to initiate a DFT scan. In this manner, initiation commands for DFT scanning may be included in a same data stream as other commands that control operation of LEDs in cascade digital communication.

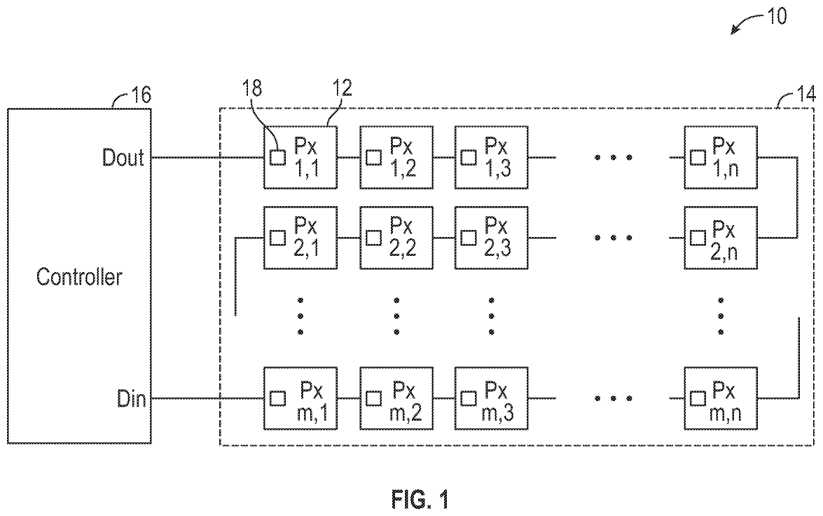

FIG. 1 is a block diagram 10 illustrating a system level control scheme for a lighting device using cascade communication for serially connected LED packages 12 according to principles of the present disclosure. The lighting device may embody an LED display and each LED package 12 may form an LED pixel of the display. For such applications, the terms LED package and LED pixel may be used interchangeably, although it is recognized that an LED package may be composed of several LED pixels formed together in one component. An exemplary LED string 14 arranged for serial communication is indicated by a dashed box in FIG. 1. While only the single LED string 14 is provided in detail, one or more other LED strings may also be coupled with a controller 16. The controller 16 may comprise an integrated circuit, such as one or more of an ASIC, a microcontroller, a programmable control element, and an FPGA. In certain embodiments, the controller 16 may be referred to as a master controller for the LED string 14. In other embodiments, the controller 16 may be a sub-controller to which another master controller (not shown) delegates a set of tasks as it pertains to a larger system. A data signal out (Dout) of the controller 16 may be passed along the LED string 14 in a serial manner, and a return data signal in (Din) may be received back by the controller 16. The signal may include an original clock domain provided by the controller 16 or another master controller as described above. In FIG. 1, each LED package 12, or LED pixel, is provided with a label such as “Px 1,1” where the first number represents a row, and the second number represents a column. Each LED package 12 includes its own active electrical element 18 that is registered and housed therewithin so that each LED package 12 comprises logic for responding to received data signals.

According to the arrangement of FIG. 1, important aspects include the capability of performing testing, such as DFT scanning, to ensure proper operation of the active electrical elements 18. As disclosed herein, LED packages 12 and related methods are disclosed where initiation commands for DFT scanning are included in the same data stream as other commands. In response to receiving a scan initiation command, the active electrical elements 18 may generate an internal TMS signal that triggers internal scanning logic to initiate the test mode and to send and receive the scan data on the data stream. The scan initiation command may be implemented in the same manner as other commands and data such as those that control brightness and other parameters. As such, any LED package 12 within the LED string 14 may be addressed for the DFT scan.

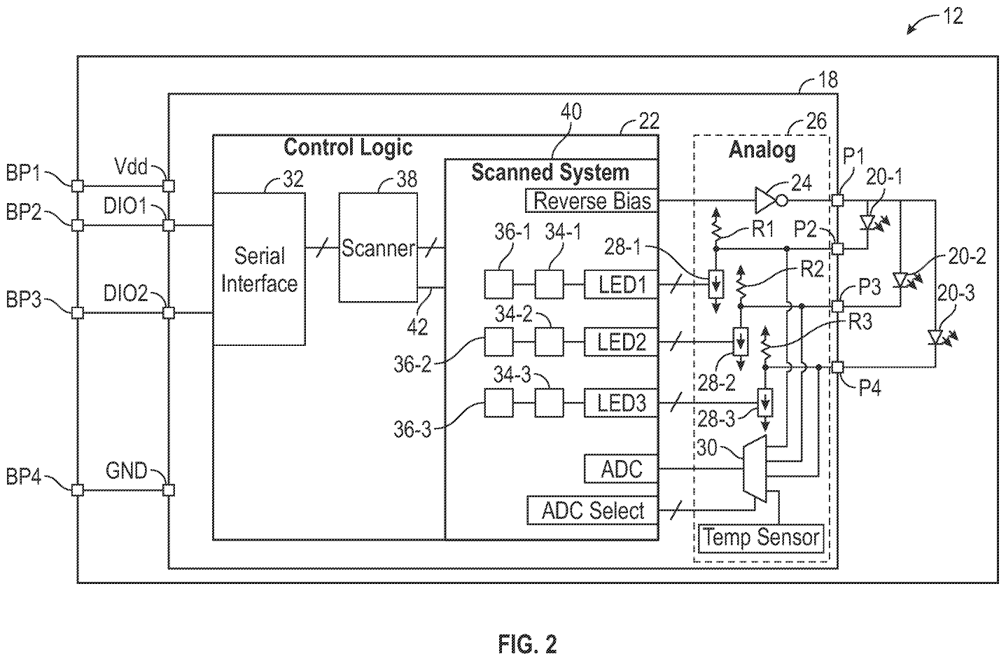

FIG. 2 is a block diagram of an LED package 12 from FIG. 1 capable of DFT scanning according to principles of the present disclosure. The active electrical element 18 may include multiple ports or terminals represented by a supply voltage (Vdd), ground (GND), and bidirectional communication ports or digital input/output ports (DIO1 and DIO2) according to embodiments disclosed herein. The Vdd, GND, DIO1, and DIO2 ports are coupled to corresponding bond pads BP1 to BP4 of the LED package 12. The bond pads BP1 to BP4 form electrical pads that are configured to receive signals that are external to the LED package 12. In certain embodiments, the bond pads BP1 to BP4 are configured to be mounted and bonded to another surface (e.g., a mounting surface of an LED panel that includes electrical traces or other types of signal lines) to receive external signals. In other embodiments, the bond pads BP1 to BP4 may be configured to receive external signals by way of wire bonds.

By having the DIO1 and DIO2 ports configured as bidirectional ports, the active electrical element 18 may advantageously be able to detect an input signal from a communication channel and then assign one of the DIO1 and DIO2 ports as an input port and the other of the DIO1 and DIO2 ports as the output port. Such functionality may be provided by input/output buffers and/or an active switching network internal to the active electrical element 18 and electrically coupled to the DIO1 and DIO2 ports. This provides flexibility in layouts for displays where a plurality of LED packages 12 are connected together for cascade communication. For example, multiple LED packages 12 may be arranged in multiple rows where data cascades from package-to-package along each row and in a serpentine manner from row-to-row as illustrated in FIG. 1. In such arrangements, the bidirectional communication ports allow the LED packages 12 to be mounted in a same orientation and receive and transmit digital communication left-to-right or right-to-left depending on the row position. In addition to the four ports of Vdd, GND, DIO1, and DIO2 on the left side of the block diagram, the active electrical element 18 includes four ports P1 to P4 on the right side that are coupled with LEDs 20-1 to 20-3 of the LED package 12. In this regard, the LEDs 20-1 to 20-3 are packaged together with the active electrical element 18 in the common LED package 12 to form an individual pixel of a larger display. As used herein, the LEDs 20-1 to 20-3 may also be referred to as LED chips.

Certain elements of the active electrical element 18 are described below; however, it is understood that the active electrical element 18 may include many other components, including memory elements, signal conditioning elements, thermal management, electrostatic discharge elements, clock elements, and oscillators, among others. In FIG. 2, control logic 22 is arranged to receive input data, execute commands according to a command protocol, provide control signals for operation of the LEDs 20-1 to 20-3, report various voltage levels and/or temperature levels included with output data, and transmit the output data via the DIO1 and DIO2 ports to the next adjacent LED package. The control logic 22 may operate in the digital domain and may include input/output buffers electrically coupled to the DIO1 and DIO2 ports that assign input and output configurations for the bidirectional DIO1 and DIO2 ports.

In certain embodiments, the active electrical element 18 may be configured to provide both forward and reverse bias states to the LEDs 20-1 to 20-3. In this regard, the control logic 22 may include a reverse bias control output signal that, with appropriate active elements, is configured to supply either near-Vdd or near-GND voltage levels to the LEDs 20-1 to 20-3. Since the nomenclature “reverse bias” implies that a high level on the control logic 22 output produces a reverse bias condition, the output signal could simply be coupled with an inverter 24 that is provided in a driver 26 of the active electrical element 18. As such, the LEDs 20-1 to 20-3 may be either forward biased or reverse biased depending on a particular operating state and/or command received by the control logic 22. The inverter 24, or inverter logic element, may have sufficient output characteristics to drive the LEDs 20-1 to 20-3. The driver 26 may be substantially an analog interface of the active electrical element 18 that is electrically coupled with the control logic 22. The driver 26 may include controllable current sources 28-1 to 28-3, which could also be configured as LED sink drivers. Pull-up resistors R1 to R3 may be incorporated to provide paths to Vdd for each of the LEDs 20-1 to 20-3, which aid with the voltage measurement when configured for reverse bias. Each of the current sources 28-1 to 28-3 may be electrically coupled with digital output signals LED1 to LED3 of the control logic 22. The output signals LED1 to LED3 may be provided along multiple wires that are coupled to each of the current sources 28-1 to 28-3 for current selection purposes. The output signals LED1 to LED3 may embody PWM outputs of the control logic 22 for controlling operation of the LEDs 20-1 to 20-3. Each current source 28-1 to 28-3 in FIG. 2 may include multiple current sources at varying current levels to provide varying current PWM control to each LED chip 20-1 to 20-3. In this regard, each current source 28-1 to 28-3 may be referred to as an overall current source for a particular one of the LED chips 20-1 to 20-3 such that each overall current source is composed of multiple individual current sources at different current levels. The driver 26 may also include a multiplexer 30 electrically coupled with an analog-to-digital (ADC) converter and ADC selector of the control logic 22. Additionally, the driver 26 may include an on-chip temperature sensor that is provided through the multiplexer 30. In certain embodiments, the temperature sensor provides thermal compensation for the LEDs 20-1 to 20-3 via a thermal compensation curve and/or thermal shut down.

The active electrical element 18 further comprises a serial interface 32 that embodies a module with circuitry configured to decode and convert the incoming signal of the data stream into a bitstream in a local clock domain, which can be further processed by the control logic 22. In this manner, the serial interface 32 may also be referred to as a digital communication receiving device. The digital communication could be received from a controller (e.g., 16 of FIG. 1) and/or another LED package (e.g., 12 of FIG. 1) in a serial string. The serial interface 32 may receive compressed data and retransmit a combination of the same data along with modified data to the communication channel to which another LED package or another external element is connected in a manner that is compatible with the overall LED display system.

In certain embodiments, the control logic 22 may include circuitry in the form of one or more PWM processors 34-1 to 34-3 that provide the output PWM signals LED1 to LED3. A separate PWM processor 34-1 to 34-3 may be provided for each LED chip 20-1 to 20-3, or the PWM processors 34-1 to 34-3 may be combined as single PWM processor for all of the LED chips 20-1 to 20-3. In certain embodiments, the one or more PWM processors 34-1 to 34-3 are configured to transform input PWM signals and then shift the transformed PWM values so pulse widths are provided to the LED chips 20-1 to 20-3 that compensate for delayed turn-on times.

The control logic 22 may further include circuitry in the form of one or more decoders 36-1 to 36-3 that have outputs that feed the PWM processors 34-1 to 34-3. A separate decoder 36-1 to 36-3 may be provided for each LED chip 20-1 to 20-3, or the decoders 36-1 to 36-3 may be combined as single decoder for all of the LED chips 20-1 to 20-3. The decoders 36-1 to 36-3 are configured to decode the compressed data received by the serial interface 32.

In order to implement DFT scanning, the active electrical element 18 may include scanner circuitry 38 coupled to the serial interface 32. As illustrated, scanned system circuitry 40 that is subject to DFT scanning and testing may include various elements of the control logic 22, including the PWM processors 34-1 to 34-3 and the decoders 36-1 to 36-3, among others. The scanner circuitry 38 is positioned in portions of the communication channel that are between the serial interface 32 and the scanned system circuitry 40. In certain embodiments, the scanner circuitry 38 may embody its own state machine within the active electrical element 18.

During normal operation, the scanner circuitry 38 is effectively transparent and simply passes through commands and other data for controlling the LED chips 20-1 to 20-3. When an initiation command for DFT scanning is received by the serial interface 32, the scan initiation command passes through the scanner circuitry 38 and is received by the scanned system circuitry 40. Upon receipt of the scan initiation command, the scanned system circuitry 40 generates a TMS signal that is sent back to scanner circuitry 38 via a return communication channel 42 between the scanned system circuitry 40 and the scanner 38. In this regard, the TMS signal may be referred to as a command based TMS signal since it is generated based on receipt of the scan initiation command. In conventional DFT scanning for integrated circuits, the TMS signal is based on a pure signal sent from an external device along a dedicated communication line. By arranging the active electrical element 18 according to principles of the present disclosure, no additional communication line is needed. Rather, the command based TMS signal is internally generated based on receipt of the scan initiation command via a common communication channel for other commands. Additionally, the LED package 12 itself does not need an extra bond pad (BP1 to BP4 of FIG. 2) to enable DFT scanning capabilities, thereby permitting dimensions of the LED package 12 to remain suitable for use as a pixel in fine pitch video displays.

In certain embodiments, the TMS signal may comprise a signal pulse to the scanner circuitry 38. The TMS signal triggers the scanner circuitry 38 to enter a scan mode such that the scanner circuitry 38 controls the scanned system circuitry 40 and associated clock during the scan mode. In this manner, the scanned system circuitry 40 may be placed in a halt mode during scanning and testing. During scan mode, the scanner circuitry 38 may read and/or replace current states in the scanned system circuitry 40. When scanning is complete, the scanner circuitry 38 returns to transparent mode and normal operation is resumed in the scanned system circuitry 40.

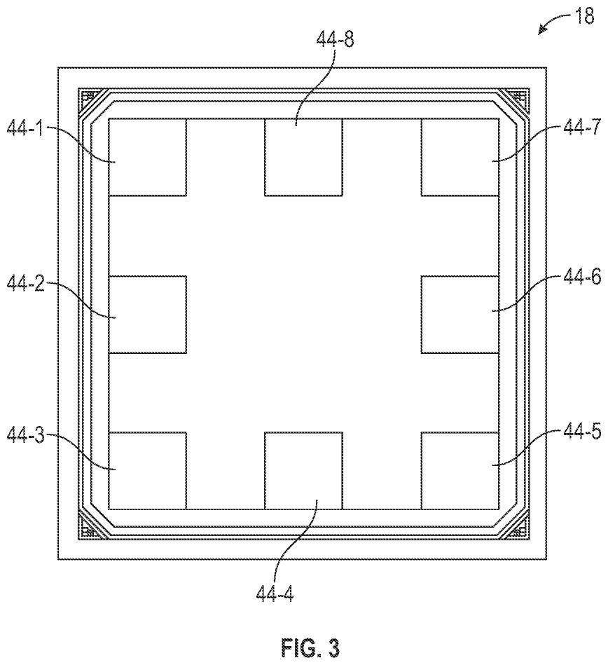

FIG. 3 is a top view of an active electrical element 18 capable of DFT scanning according to principles of the present disclosure. As illustrated, the active electrical element 18 may include eight ports 44-1 to 44-8. In the example of FIG. 2, the ports 44-1 to 44-8 are the Vdd, GND, DIO1, and DIO2 ports as well as the P1 to P4 ports coupled to the LED chips 20-1 to 20-3. As described above for FIG. 2, certain embodiments provide forward and reverse bias states for the LED chips (e.g., port P1 of FIG. 2). For embodiments without reverse bias capabilities, only three total ports P2 to P4 may be coupled to the LED chips for a total of seven ports for the active electrical element. By having DFT scanning triggered by command-based communication as described above, no additional ports are needed. For example, if the port 44-1 is the DIO1 port, the port 44-1 forms a data input port that receives commands and data for controlling operation of the LED chips (20-1 to 20-3 of FIG. 2) and also receives the scan initiation command described above for initiating DFT scanning. In the example where the DIO1 and DIO2 ports are bidirectional ports, one of the DIO1 or DIO2 ports will be assigned the data input port upon receipt of the incoming data stream and the other of the DIO1 and DIO2 ports will be assigned the data output port. In this manner, the overall size of the active electrical element 18 and corresponding LED package (12 of FIG. 2) may be small enough so the LED package (12 of FIG. 2) may form an LED pixel for fine pitch video applications. Accordingly, dimensions of the active electrical element 18 may be sufficiently small to fit within the LED package (12 of FIG. 2) along with the LED chips (20-1 to 20-3 of FIG. 2) without increasing overall dimensions thereof. In certain embodiments, other ports may be provided for functions beyond DFT scanning, such as environmental sensing and/or touch sensing, among others.

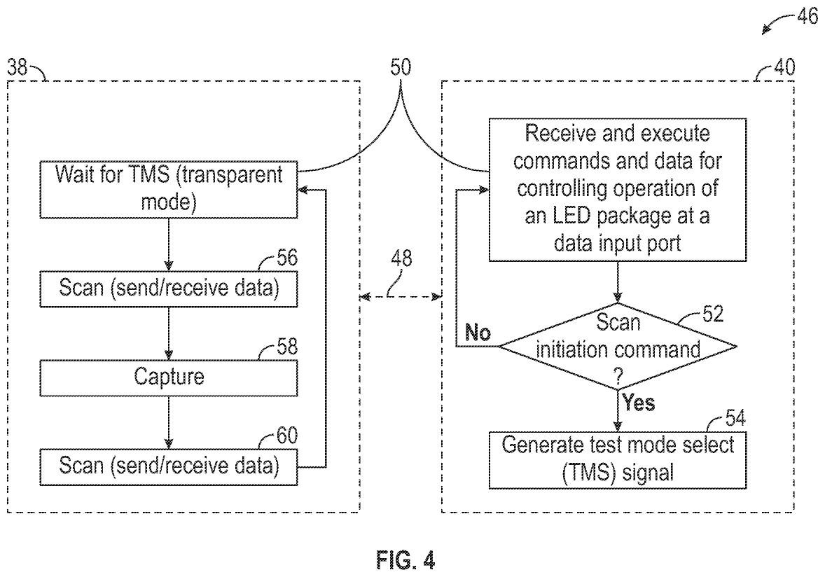

FIG. 4 is a schematic diagram illustrating a general process flow 46 for a method of implementation of DFT scanning according to principles of the present disclosure. Two dashed-line boxes are shown to generally represent the scanned system circuitry 40 and the scanner circuitry 38. Steps of the process flow 46 within a particular dashed-line box take place or are the responsibility of the corresponding scanned system circuitry 40 and/or scanner circuitry 38. A double-arrow dashed line 48 represents communication between the scanned system circuitry 40 and the scanner circuitry 38 within the active electrical element. Communication may include serial data of a data stream, scan initiation and/or enable commands, clock signals, and resent signals, among others.

In a first step 50, commands and data for controlling operation of an LED package and corresponding LED chips are received from a data input port and decoded. With reference to FIG. 2, the first step 50 provides normal operation where the commands and data are received by the active electrical element 18 and scanned system circuitry 40 for controlling operation of the LED package 12 and corresponding LED chips 20-1 to 20-3. During the normal operation of the first step 50, the scanner circuitry 38 is effectively in a transparent mode while waiting for a TMS signal. In a second step 52, the scan initiation command for DFT scanning may be received at the same data input port. As described above, the data input port may embody the DIO1 or the DIO2 port as illustrated in FIG. 2. In this manner, the first step 50 and the second step 52 are both provided by an incoming data stream to the same data input port. If a scan initiation command is not received, the LED package 12 stays in a normal operation mode according to the first step 50. When a scan initiation command is received, the TMS signal is internally generated based on the scan initiation command at a third step 54. In the context of FIG. 2, the TMS signal is generated within the scanned system circuitry 40 after receiving the scan initiation command via the serial interface 32 and the scanner circuitry 38.

After generation of the TMS signal within the scanned system circuitry 40, the TMS signal is sent to the scanner circuitry 38. Upon receipt, the scanner circuity 38 exits the transparent mode and initiates a scan, such as DFT scanning. In FIG. 4, the scanning is generally shown as scan-capture-scan sequence for DFT scanning. In the manner, a fourth step 56 involves a scan (send/receive data), a fifth step 58 involves data capture, and a sixth step 60 is another scan (scan/receive data). In practice, the scan may include multiple sequences as described for the fourth, fifth, and sixth steps 56, 58, 60 to test some or all logic within the scanned system circuitry 40. When the scan is complete, the scanner circuitry 38 returns to transparent mode at the first step 50. As indicated above, the scanned system circuitry 40 is in normal operation mode during the first step 50 and operates according to states of its registers. After scanning by the scanner circuitry 38, resulting replacement vector codes may be fed into the scanned system circuitry 40 to resume operation. In the context of FIG. 2, the process flow 46 described above for FIG. 4 may take place at or within the active electrical element 18.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
at least one LED chip;
an active electrical element electrically connected to the at least one LED chip, the active electrical element configured to implement design for test (DFT) scanning; and
a data input port configured to receive commands and data for controlling operation of the at least one LED chip, the data input port configured to receive a scan initiation command to initiate DFT scanning within the active electrical element.

2. The LED package of claim 1, wherein the data input port is a first bidirectional communication port.

3. The LED package of claim 2, wherein the active electrical element is configured to detect an input signal at the first bidirectional communication port, assign the first bidirectional communication port as the data input port, and assign a second bidirectional communication port as a data output port.

4. The LED package of claim 1, wherein:
the at least one LED chip comprises three LED chips; and
the active electrical element comprises no more than eight total ports that include the data input port, a data output port, a ground port, a supply voltage port, and no more than four ports coupled to the three LED chips.

5. The LED package of claim 4, wherein the active electrical element comprises no more than three ports coupled to the three LED chips.

6. The LED package of claim 1, wherein the active electrical element comprises a serial interface coupled to the data input port configured to receive the commands and data for controlling operation of the at least one LED chip and the scan initiation command.

7. The LED package of claim 6, further comprising scanner circuitry coupled to the serial interface, the scanner circuitry configured to pass the commands and data for controlling operation of the at least one LED chip and the scan initiation command to other circuitry of the active electrical element.

8. The LED package of claim 7, wherein the other circuitry forms scanned system circuitry of the active electrical element, and upon receipt of the scan initiation command, the scanned system circuitry generates a test mode select (TMS) signal that is sent to the scanner circuitry for initiating DFT scanning.

9. The LED package of claim 1, wherein the active electrical element comprises an application-specific integrated circuit (ASIC).

10. A method of testing for a light-emitting diode (LED) device, the method comprising:
receiving commands and data at a data input port, the commands and data configured for controlling operation of at least one LED chip;
receiving a scan initiation command for initiation of design for test (DFT) scanning at the data input port; and
generating a test mode select (TMS) signal based on the scan initiation command.

11. The method of claim 10, wherein the data input port is a terminal of an active electrical element of the LED device.

12. The method of claim 11, wherein generating the TMS signal comprises receiving the scan initiation command at scanned system circuitry of the active electrical element.

13. The method of claim 12, further comprising sending the TMS signal to scanner circuitry of the active electrical element and implementing DFT scanning of the scanned system circuitry.

14. An active electrical element for controlling operation of at least one light-emitting diode (LED) chip, the active electrical element comprising:
a serial interface configured to receive commands and data for controlling operation of the at least one LED chip and a scan initiation command to initiate design for test (DFT) scanning;
scanner circuitry coupled to the serial interface; and
scanned system circuitry coupled to the scanner circuitry, the scanned system circuitry configured to generate a test mode select (TMS) signal based on the scan initiation command and send the TMS signal to the scanner circuitry for initiating DFT scanning.

15. The active electrical element of claim 14, wherein the scanner circuitry is configured to pass the commands and data for controlling operation of the at least one LED chip and the scan initiation command to the scanned system circuitry before the TMS signal is generated.

16. The active electrical element of claim 14, further comprising a data input port that is configured to receive both the scan initiation command and the commands and data for controlling operation of the at least one LED chip.

17. The active electrical element of claim 16, wherein the data input port is a first bidirectional communication port.

18. The active electrical element of claim 17, wherein the active electrical element is configured to detect an input signal at the first bidirectional communication port, assign the first bidirectional communication port as the data input port, and assign a second bidirectional communication port as a data output port.

19. The active electrical element of claim 16, further comprising a data output port, a ground port, a supply voltage port, and ports for coupling to one or more LED chips.

20. The active electrical element of claim 14, wherein the serial interface, the scanner circuitry, and the scanned system circuitry are part of an application-specific integrated circuit (ASIC).
